(19) United States
(12) Patent Application Publication
(10) Pub. No.: US 2014/0246696 A1
(43) Pub. Date: Sep. 4, 2014

(54) TRANSISTOR WITH EMBEDDED STRAIN-INDUCING MATERIAL FORMED IN CAVITIES FORMED IN A SILICON/GERMANIUM SUBSTRATE

(71) Applicant: GLOBALFOUNDRIES INC., Grand Cayman (KY)

(72) Inventors: Stefan Flachowsky, Dresden (DE); Roman Boschke, Dresden (DE); Ralf Illgen, Dresden (DE)

(73) Assignee: GLOBALFOUNDRIES Inc., Grand Cayman (KY)

(21) Appl. No.: 13/783,547

(22) Filed: Mar. 4, 2013

(51) Int. Cl. H01L 29/78; H01L 29/66

(52) U.S. Cl. CPC H01L 29/7848; H01L 29/66477
USPC 257/190; 438/285

(57) ABSTRACT

When forming sophisticated semiconductor devices including N-channel transistors with strain-inducing embedded source and drain semiconductor regions, N-channel transistor performance may be enhanced by selectively growing embedded pure silicon source and drain regions in cavities exposing the silicon/germanium layer of a Si/SiGe-substrate, wherein the silicon layer of the Si/SiGe-substrate may exhibit a strong bi-axial tensile strain. The bi-axial tensile strain may improve both electron and hole mobility.

### BACKGROUND OF THE INVENTION

1. Field Of The Invention

Generally, the present disclosure relates to the fabrication of integrated circuits, and, more particularly, to transistors having strained channel regions by using embedded semiconductor materials so as to enhance charge carrier mobility in the channel regions of the transistors.

2. Description Of The Related Art

The fabrication of complex integrated circuits requires a large number of transistor elements, which represent the dominant circuit element for complex circuits, to be formed in a die region. For example, several hundred millions transistors may be provided in presently available complex integrated circuits. Generally, a plurality of process technologies is currently practiced, wherein, for complex circuitry, such as microprocessors, storage chips and the like, CMOS technology is currently the most promising approach due to the superior characteristics in view of operating speed and/or power consumption and/or cost efficiency. In CMOS circuits, complementary transistors, i.e., P-channel transistors and N-channel transistors, are used for forming circuit elements, such as inverters and other logic gates to design highly complex circuit assemblies. During the fabrication of complex integrated circuits using CMOS technology, transistors, i.e., N-channel transistors and P-channel transistors, are formed on a substrate including a crystalline semiconductor layer. A MOS transistor, or generally a field effect transistor, irrespective of whether an N-channel transistor or a P-channel transistor is considered, comprises so-called PN junctions that are formed by an interface of highly doped drain and source regions with an inversely or weakly doped channel region disposed between the drain region and the source region. The conductivity of the channel region, i.e., the drive current capability of the conductive channel, is controlled by a gate electrode formed in the vicinity of the channel region and separated therefrom by a thin insulating layer. The conductivity of the channel region, upon formation of a conductive channel due to the application of an appropriate control voltage to the gate electrode, depends on, among other things, the dopant concentration, the mobility of the charge carriers and, for a given extension of the channel region in the channel width direction, the distance between the source and drain regions, which is also referred to as channel length. Thus, the reduction of the channel length, and associated therewith the reduction of the channel resistivity, is a dominant design criterion for accomplishing an increase in the operating speed of the integrated circuits.

The continuing shrinkage of the transistor dimensions, however, involves a plurality of issues associated therewith that have to be addressed so as to not unduly offset the advantages obtained by steadily decreasing the channel length of MOS transistors. For example, highly sophisticated dopant profiles, in the vertical direction as well as in the lateral direction, are required in the drain and source regions so as to provide low sheet and contact resistivity in combination with desired channel controllability. Moreover, the gate dielectric material may also be adapted to the reduced channel length in order to maintain the required channel controllability. However, some mechanisms for maintaining high channel controllability may also have a negative influence on the charge carrier mobility in the channel region of the transistor, thereby partially offsetting the advantages gained by the reduction of the channel length.

Since the continuous size reduction of the critical dimensions, i.e., the gate length of the transistors, necessitates the adaptation and possibly the new development of highly complex process techniques and may also contribute to less pronounced performance gain due to mobility degradation, it has been proposed to enhance the channel conductivity of the transistor elements by increasing the charge carrier mobility in the channel region for a given channel length, thereby enabling a performance improvement that is comparable with the advance to a technology standard that would require extremely scaled critical dimensions, while avoiding or at least postponing many of the process adaptations associated with device scaling.

One efficient mechanism for increasing the charge carrier mobility is the modification of the lattice structure in the channel region, for instance by creating tensile or compressive stress in the vicinity of the channel region so as to produce a corresponding strain in the channel region, which results in a modified mobility for electrons and holes, respectively. For example, creating bi-axial tensile strain and/or uni-axial tensile strain in the channel region for a standard crystallographic configuration of the active silicon material, i.e., a (100) surface orientation with the channel length aligned to the <110> direction, increases the mobility of electrons, which, in turn, may directly translate into a corresponding increase in conductivity. On the other hand, compressive uni-axial strain in the channel region exerted in the channel length direction and tensile strain exerted in the channel width direction may increase the mobility of holes, thereby providing the potential for enhancing the performance of P-type transistors. The introduction of stress or strain engineering into integrated circuit fabrication is an extremely promising approach, since strained silicon may be considered as a “new” type of semiconductor material, which may enable the fabrication of fast powerful semiconductor devices without requiring expensive semiconductor materials, while many of the well-established manufacturing techniques may still be used.

Consequently, it has been proposed to introduce, for instance, a silicon/germanium (SiGe) material laterally next to the channel region of PMOS transistors so as to induce an uni-axial compressive stress that may result in a corresponding compressive strain in the channel region of PMOS transistors and a silicon/carbon (SiC) material laterally next to the channel region of NMOS transistors so as to induce a uni-axial tensile stress that may result in a corresponding tensile strain in the channel region of NMOS transistors. When forming the silicon/germanium material, the drain and source regions of the PMOS transistors are selectively recessed to form cavities, while the NMOS transistors are masked, and subsequently the silicon/germanium material is selectively formed in the cavities of the PMOS transistor by epitaxial growth. Furthermore, when forming the silicon/carbon material, the drain and source regions of the NMOS transistors are selectively recessed to form cavities, while the PMOS transistors are masked, and subsequently the silicon/carbon material is selectively formed in the cavities of the NMOS transistor by epitaxial growth.

Although the technique has significant advantages in view of performance gain of P-channel transistors and thus of the entire CMOS device, it turns out, however, that, in advanced semiconductor devices, the performance gain of N-channel transistors is not significant and also an increased variability of device performance may be observed, which may be associated with the above-described technique for incorporating a strained silicon/carbon alloy in the drain and source regions of N-channel transistors.

The strain-inducing effect of the embedded silicon/carbon material depends on the amount of the embedded strain-inducing carbon material, the distance with respect to the channel region and also depends on the size and shape of the strain-inducing silicon/carbon material. For example, incorporating an increased fraction of carbon may result in an increase of the resulting strain, since the corresponding lattice mismatch between the silicon/carbon material and the silicon material of the active region may be increased. The maximum concentration of carbon in the semiconductor alloy, however, may depend on the process strategy used, since further increasing the carbon concentration may result in undue carbon agglomeration, which in turn may provide increased lattice and/or silicide defects and the like. Furthermore, the amount of the strain-inducing material and the shape thereof in the drain and source regions may depend on the size and shape of the cavities formed in the drain and source areas, wherein also the effective distance from the channel region may be substantially determined on the basis of the size and shape of the cavities.

A typical conventional process flow for forming an embedded silicon/carbon or silicon/germanium material in source and drain regions of N-channel or P-channel transistors may include the following process steps. After forming the active semiconductor regions, which is typically accomplished by forming appropriate isolation regions that laterally delineate the active regions, electrode structures are formed on the basis of any appropriate process strategy. That is, appropriate materials, such as dielectric materials, electrode materials and the like, are provided in combination with one or more appropriate dielectric cap materials which may be used, in addition to its use in the actual patterning of the gate layer stack, as an etch and deposition mask in a later manufacturing stage when the embedded strain-inducing silicon/carbon or silicon/germanium material is deposited. In sophisticated applications, the gate electrode structures of field effect transistors are provided with a gate length of 50 nm and less thereby providing superior transistor performance, for instance in terms of switching speed and drive current capability. The reduced critical dimensions, however, may also contribute to a pronounced dependency of the resulting transistor performance on process variations, in particular when basically extremely scaled transistors are considered.

Based on the dielectric cap material and a sidewall spacer structure, cavities may be etched into the drain and source areas, wherein the size and shape may be substantially determined on the basis of the etch parameters of the corresponding etch process. It should be appreciated that any other transistors, in which the incorporation of a silicon/carbon or silicon/germanium material is not desired, are covered by an appropriate mask layer. After any appropriate cleaning processes for preparing exposed surface areas of the silicon material in the drain and source areas, a selective epitaxial growth process may be performed, in which the silicon/carbon or silicon/germanium material may be selectively deposited on exposed silicon surface areas, while a significant deposition of the semiconductor material on dielectric surface areas, such as dielectric cap materials, sidewall spacers, isolation regions and mask layers, may be suppressed.

As discussed above, the final gain in performance of the N-channel and P-channel transistors may depend critically on the carbon or germanium content in the strained semiconductor material. Consequently, great efforts have been made in developing a process strategy in which a high carbon or germanium content may be achieved. A high concentration of carbon, however, may lead to an increase of device failures, as will be explained in more detail with reference to FIG. 1.

FIG. 1 schematically illustrates a cross-sectional view of a semiconductor device 100 in a manufacturing stage in which complex high-k metal gate electrode structures 160A, 160B may be provided with lateral dimensions of, for instance, 50 nm and less. In this manufacturing stage, the device 100 typically comprises a substrate 101 in combination with a semiconductor layer 102, such as a silicon layer, in which a plurality of active regions are provided, wherein a first active region 112, representing an active region of N-channel transistors, and a second active region 122, representing an active region of P-channel transistors, are illustrated. Generally, an active region is to be understood as a semiconductor region of the layer 102 in and above which one or more transistors have to be formed. The first and second active regions 112, 122 are laterally delineated by an appropriately dimensioned and shaped isolation structure 103, for instance provided in the form of a shallow trench isolation. The gate electrode structure 160A may represent the gate electrode structure of an N-channel transistor 150A formed in and above the first active region 112, while the gate electrode structure 160B may represent the gate electrode structure of a P-channel transistor 150B formed in and above the second active region 122. The gate electrode structures 160A, 160B comprise a gate dielectric material 161, which may have incorporated therein a gate dielectric material so as to provide a total dielectric constant that is 10.0 and higher, which may be accomplished on the basis of materials such as hafnium oxide, hafnium silicate, zirconium oxide and the like, which are generally referred to hereinafter as high-k dielectric materials. Furthermore, a metal-containing electrode material 162, such as titanium nitride and the like, is typically provided in combination with the dielectric material 161 in order to obtain the required threshold voltage characteristics and the like. It should be noted, however, that the materials 161, 162 in the gate electrode structures 160A on the one hand, and in the gate electrode structure 160B on the other hand, may differ in their material composition, for instance with respect to a work function metal species, since typically different work functions are required for the gate electrode structures of different transistors. Furthermore, a silicon-based electrode material 163 is provided. Furthermore, a spacer structure 165, 167, for instance comprised of one or more silicon nitride layers and the like, is formed on sidewalls of the electrode material 163 and of the sensitive materials 161, 162 in the gate electrode structures 160A, 160B. An embedded silicon/carbon material 105A is provided in the source and drain regions 154 of the N-channel transistor 150A and an embedded silicon/germanium material 105B is provided in the source and drain regions 154 of the P-channel transistor 150B to provide appropriate strain conditions in the channel regions 115, 125, as indicated by the arrows 152.

The device 100 as shown in FIG. 1 may be formed on the basis of the following process strategy. The isolation structure 103 is formed by applying sophisticated lithography, etch, deposition, anneal and planarization techniques in order to form trenches and fill the trenches with an appropriate dielectric material, thereby also defining the lateral size and shape of the first and second active regions 112, 122. After incorporating any dopant species in accordance with the overall device requirements, the gate electrode structures 160A, 160B are formed, which may require complex deposition and patterning processes in order to provide the material 161, 162 for the various transistor types. That is, since typically different work function metal species have to be provided for different transistor types, a corresponding deposition, masking and patterning regime is applied, possibly followed by any thermal treatments in order to provide the materials 161 and 162 with the required characteristics. Thereafter, the electrode material 163 in combination with a cap material or materials (not shown) are deposited and subsequently patterned by using sophisticated lithography and etch strategies, thereby finally obtaining the gate electrode structures 160A, 160B with the desired critical dimensions, i.e., with a gate length of 50 nm and significantly less in sophisticated applications. Next, a spacer layer is deposited, which may include one or more deposition processes such as a multilayer deposition, possibly in combination with a low pressure chemical vapor deposition (CVD) process followed by the patterning of an etch mask, which may then be used for etching the spacer layer in order to obtain spacer elements 165, 167 of the gate electrode structures 160A, 160B. It should be appreciated that the spacer structures 165 may be used for confining the sensitive gate materials and may also act as offset spacer elements for forming source and drain extension regions 153. The spacer structures 167 may act as offset spacer elements during the further processing for forming cavities in the first and second active regions 112, 122 and for appropriately defining the deep source and drain regions in the first and second active regions 112, 122 in a further advanced manufacturing stage. Due to the patterning process of the spacer layer, generally a certain degree of material erosion may occur in exposed portions of the isolation structure 103 and the exposed cap layers (not shown), as well as in the first and second active regions 112, 122.

Subsequently, cavities are formed adjacent to the gate electrode structures 160A, 160B in the first and second active regions 112, 122, respectively, using an appropriate mask technique. The cavities are typically accomplished by applying an anisotropic plasma assisted etch process, which in some illustrative embodiments is performed as an in situ process upon patterning the spacer layer. Due to the anisotropic nature of the etch process, the resulting cavities are substantially U-shaped, wherein the depth of the cavity strongly depends on the process parameters of the corresponding plasma assisted etch process. Thereafter, the device 100 is prepared for the subsequent selective deposition of a silicon/carbon or silicon/germanium alloy in the cavities, which may involve a plurality of cleaning recipes and the like.

In a further advanced manufacturing stage, a silicon/carbon material 105A and silicon/germanium material 105B is selectively grown in the cavities, respectively on the basis of the mask technique. Typically, a process strategy is applied that requires the subsequent removal of cap layers while preserving the spacer structures 165, 167 so as to ensure integrity of the sensitive gate materials. Thereafter, a further etch process is performed, for instance on the basis of appropriate wet chemical etch recipes such as hot phosphoric acid and the like, to remove the dielectric cap layers, thereby exposing the silicon-based electrode material 163 in the gate electrode structures 160A, 160B. Subsequently, deep source and drain implantation steps may be performed to form the source and drain regions 154 defining corresponding PN junctions 151 of the N-channel transistor 150A and of the P-channel transistor 150B.

The N-channel transistor 150A is consequently formed in and above the first active region 112 on the basis of the gate electrode structure 160A and the P-channel transistor 150B is formed in and above the second active region 122 on the basis of the gate electrode structure 160B. The performance of the N-channel transistor 150A significantly depends on the strain induced in the channel region 115 by the previously grown carbon/silicon material 105A. As a high carbon concentration of, e.g., more than 5 atomic percent is difficult to achieve and may lead to carbon agglomeration and to a relevant material loss during the performed cleaning and/or etching processes, the finally achieved strain in the channel region 115 of the transistor 150A may generally be reduced.

Furthermore, metal silicide regions 156 may be provided in the drain and source regions wherein, due to the carbon agglomeration, generally a non-uniform metal silicide 156 is observed in the transistor 150A. The non-uniformity of the metal silicide material in the drain and source regions 154 of the transistor 150A may have a remarkable influence on device failures upon forming contact elements in a later manufacturing stage. Furthermore, metal silicide material 166 may be formed in the gate electrode structures 160A, 160B, thereby also providing superior conductivity of the gate electrode structures.

The metal silicide materials 156, 166 are formed, for instance, by using well-established process strategies for depositing one or more desired refractory metals, such as nickel, platinum and the like, and initiating a chemical reaction by any appropriate anneal processes.

Furthermore, a contact level (not shown) may be formed so as to enclose and passivate the transistors 150A, 150B. The contact level may comprise a first dielectric material, such as a silicon nitride material, followed by a second dielectric material, such as a silicon dioxide material and the like. To this end, any well-established deposition recipes are typically applied. After planarizing the dielectric materials, sophisticated patterning regimes are applied in order to form openings in the first and second dielectric materials wherein, in a final etch step, typically the metal silicide 156 in the drain and source regions is used as an etch stop material. Due to silicide non-uniformities, the etch stop capabilities may be significantly reduced so that the etch process may etch through the metal silicide material 156 and deeply into the active region 112 which, upon filling the contact openings with a conductive material, may result in a short-circuiting of the drain and source regions, thereby at least significantly altering the transistor characteristics or even contributing to a total device failure.

Consequently, using silicon/carbon in providing a strain-inducing semiconductor alloy in sophisticated transistors may, thus, result in insufficient performance of N-channel transistors and pronounced transistor variability and significant yield losses.

In view of the situation described above, the present disclosure relates to manufacturing techniques and semiconductor devices in which strain-inducing materials may be incorporated into the active region of transistors, while avoiding, or at least reducing, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

The present disclosure generally provides manufacturing techniques and semiconductor devices in which superior transistor performance may be achieved by improving the strain conditions in N-channel transistors, which may be accomplished by providing a bi-axially strained silicon layer of a silicon-silicon/germanium substrate and an embedded source/drain silicon region arranged in cavities formed in the silicon layer and extending to the silicon/germanium layer of the substrate. The method enables a further scaling of complex semiconductor devices.

One illustrative method disclosed herein includes providing a substrate having a silicon layer formed on a silicon/germanium layer and forming an isolation structure extending through the silicon layer and through the silicon/germanium layer to define an active region. The method further includes forming a gate electrode structure including a spacer structure on the silicon layer. The method further includes forming cavities in the active region adjacent to the gate electrode structure, wherein the cavities extend through the silicon layer to expose the silicon/germanium layer, and selectively growing silicon in the cavities using the exposed silicon/germanium layer as a template layer.

One illustrative semiconductor device disclosed herein includes a substrate having a silicon/germanium layer and a silicon layer formed on the silicon/germanium layer and an active region defined by an isolation structure extending through the silicon layer and through the silicon/germanium layer. The semiconductor device further includes a gate electrode structure having a spacer structure, wherein the gate electrode structure is formed on the silicon layer and an embedded strained silicon region is formed on the silicon/germanium layer in source and drain regions of an N-channel transistor.

A further illustrative semiconductor device disclosed herein includes a substrate having a silicon-silicon/germanium-silicon layer stack defining an upper silicon layer and a lower silicon layer and a first and a second active region defined by isolation structures extending through the silicon-silicon/germanium-silicon layer stack. The semiconductor device further includes a first and a second gate electrode structure having spacer structures, the first and second gate electrode structures being formed on the upper silicon layer of the silicon-silicon/germanium-silicon layer stack. The semiconductor device further includes embedded strained silicon regions formed on the silicon/germanium layer in source and drain regions of a transistor formed in the first active region and embedded strained silicon/germanium regions formed on the lower silicon layer in source and drain regions of a transistor formed in the second active region.

### BRIEF DESCRIPTION OF THE DRAWINGS

The disclosure may be understood by reference to the following description taken in conjunction with the accompanying drawings, in which like reference numerals identify like elements, and in which:

FIG. 1 schematically illustrates a cross-sectional view of a complex semiconductor device including a strain-inducing semiconductor alloy in an N-channel transistor formed according to a conventional process strategy;

FIGS. 2a-2g schematically illustrate cross-sectional views of a semiconductor device during various manufacturing stages when forming a strain-inducing silicon drain/source region providing improved strain conditions in N-channel transistors, according to the present invention;

FIGS. 3a-3b schematically illustrate cross-sectional views of semiconductor devices formed in and on a silicon-silicon/germanium substrate, according to the present invention; and

FIG. 4 schematically illustrates a cross-sectional view of a CMOS device formed on a silicon-silicon/germanium-silicon substrate, according to the present invention.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure contemplates manufacturing techniques and semiconductor devices in which superior stress conditions in the channel region of N-channel transistors may be obtained on the basis of a strained silicon-silicon/germanium substrate and on the basis of an embedded strain-inducing silicon material selectively grown in source and drain cavities extending to the silicon/germanium layer of the substrate. The silicon layer formed on the silicon/germanium layer may comprise a bi-axial tensile strain that may improve both electron and hole mobility and thus performance of N-channel and P-channel transistors. The bi-axial tensile strain may be achieved, e.g., by forming the silicon-silicon/germanium layer stack on a silicon substrate layer.

Furthermore, due to the employment of silicon as an embedded strain-inducing source/drain material, material losses in the source and drain regions may be significantly reduced compared to conventional strategies, thereby increasing the efficiency of the strain-inducing mechanism without requiring an increased size of the cavities and/or requiring a different geometry, i.e., increased fill height of the initially-provided strain-inducing silicon material. Furthermore, due to the employment of silicon, and due to the general reduced loss of strain-inducing semiconductor material, also superior conditions are achieved to form contact elements, thereby significantly reducing the probability of etching through a metal silicide when forming contact openings that connect to the active regions of N-channel transistors.

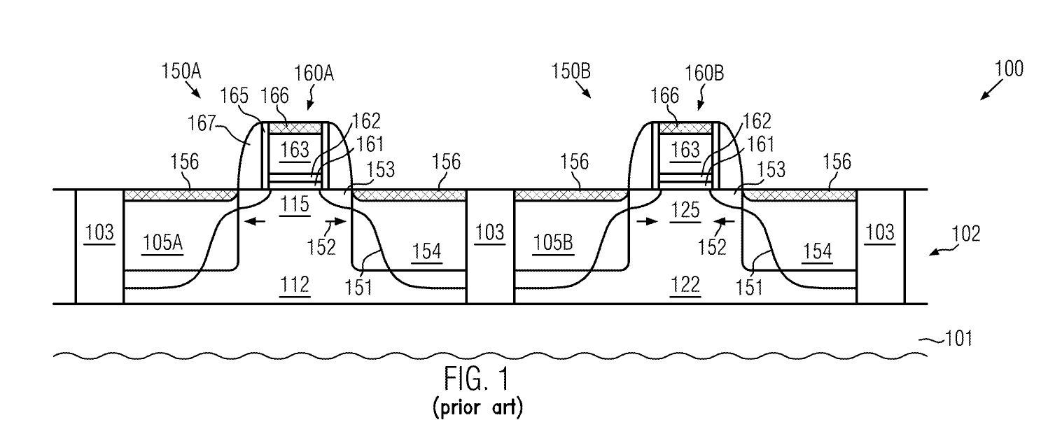

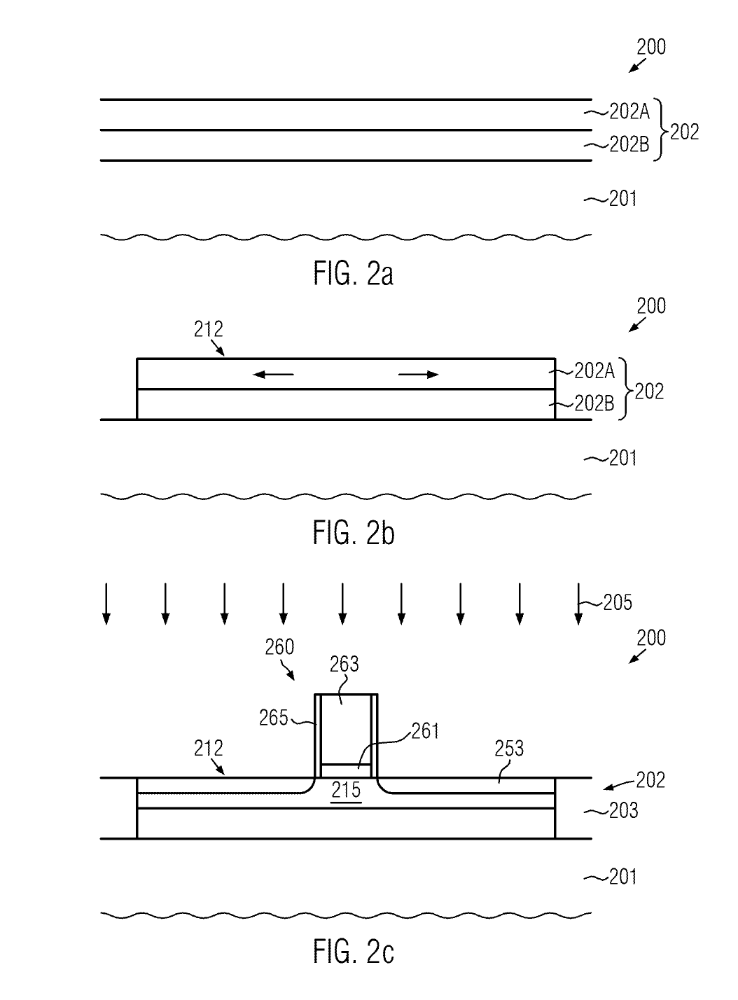

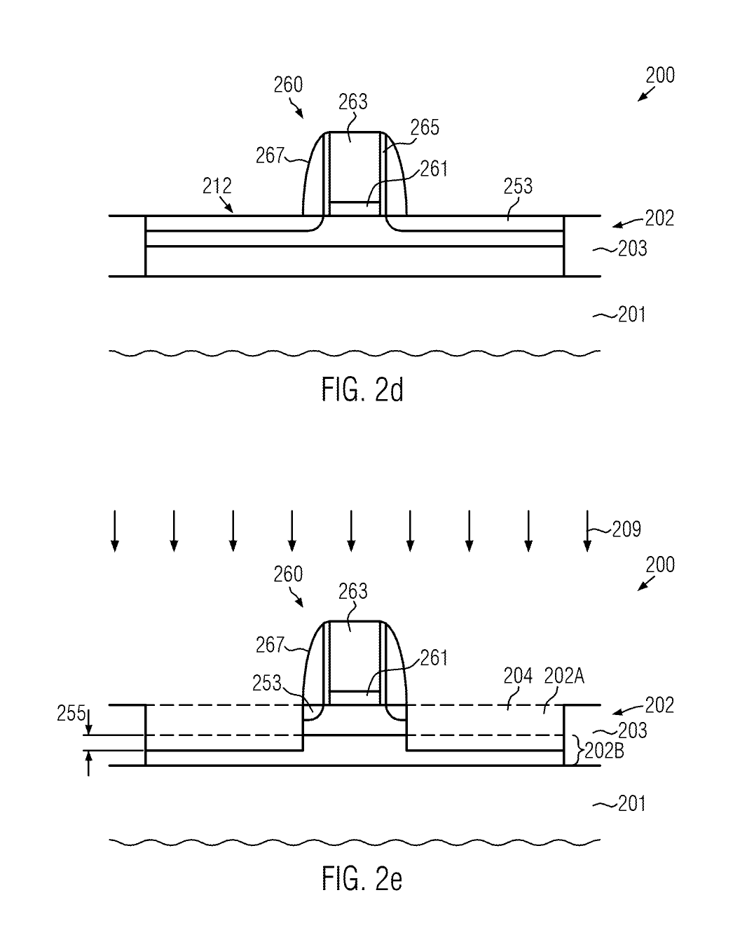

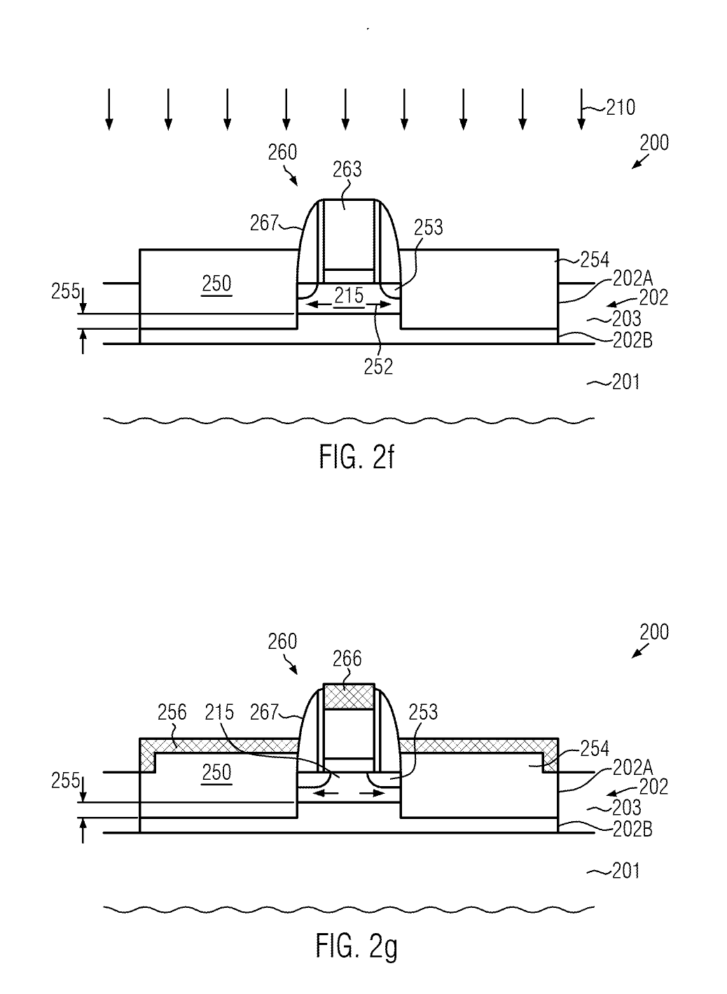

With reference to FIGS. 2a-2g, 3a-3b and 4, further illustrative embodiments will now be described in more detail, wherein reference also may be made to FIG. 1, if appropriate.

FIG. 2a schematically illustrates a cross-sectional view of a substrate 201 that provides the basis for a semiconductor device 200. The substrate 201 includes a semiconductor layer 202 having a silicon/germanium sub-layer 202B and a silicon sub-layer 202A. The thickness of the silicon sub-layer 202A is in the range of approximately 5-50 nm. More typically, the thickness of the silicon/germanium sub-layer 202B is in the range of approximately 8-20 nm. The silicon/germanium sub-layer 202B content may be approximately 20-40 atomic percent germanium. More typically, the germanium content is in the range of approximately 25-35 atomic percent. The term “atomic percent germanium” is used herein to denote the percent of atoms that are germanium within a silicon/germanium layer or region. The thickness of the silicon/germanium sub-layer 202B is in the range of approximately 10-200 nm. More typically, the thickness of the silicon/germanium sub-layer 202B is in the range of approximately 20-80 nm. The semiconductor layer 202 may be formed so as to directly connect to a crystalline silicon material of the substrate 201 if a bulk architecture is considered, as shown in FIG. 2a, while, in other cases, a silicon-on-insulator (SOI) architecture may be provided when a buried insulating material (not shown) is formed below the semiconductor layer 202. In SOI applications, the silicon/germanium sub-layer 202B may be arranged directly on the buried insulating material or on an additional silicon substrate layer formed above the buried insulating material. The semiconductor layer 202 may be provided as a continuous semiconductor material in an initial state.

FIG. 2b schematically illustrates a cross-sectional view of a semiconductor device 200 in a further advanced process stage in which the continuous semiconductor material of layer 202 is divided in active regions, such as active region 212. Generally, an active region is to be understood as a semiconductor region of the layer 202 in and above which a transistor, such as an N-channel field effect transistor, is to be formed. The active region 212 may be defined by a trench etch process that is performed by an anisotropic etch process forming a trench extending through the silicon sub-layer 202A and through the silicon/germanium sub-layer 202B so that the substrate 201 is exposed. During the etch process, the strained silicon/germanium sub-layer 202B can elastically relax and consequently a bi-axial tensile strain is generated in the silicon sub-layer 202A.

FIG. 2c schematically illustrates the device 200 after forming shallow trench isolation (STI) structures 203 which electrically separate the active region 212 from surrounding active regions. The STI regions 203 may be accomplished on the basis of well-established isolation techniques as is, for instance, described above with reference to device 100.

Moreover, in this manufacturing stage, a gate electrode structure 260 may be formed above the active region 212, which may have any appropriate configuration and may include a gate dielectric material 261, which may be silicon oxide, silicon oxynitride and/or a high-k dielectric material. In case a high-k dielectric material is employed, the high-k dielectric component may be followed by a metal-containing electrode material (not shown), as described above with reference to device 100. The gate electrode 260 may further include a silicon-containing semiconductor electrode material 263 that may be followed by a dielectric cap layer or a cap layer system (not shown) as is, for instance, also described above with reference to device 100. The silicon-containing semiconductor gate electrode material 263 may be formed on the metal-containing electrode material or directly on the silicon oxide and/or silicon oxynitride layers, when a corresponding gate dielectric layer 261 is employed. In some illustrative embodiments, a sidewall spacer structure 265 may be formed on the sidewalls of the gate electrode material 263 and of the gate dielectric material 261 by depositing one or more material layers, such as a silicon nitride layer, and patterning the same in an anisotropic etch process thereby forming the spacer structures 265.

Moreover, in this manufacturing stage, an implantation sequence 205 including a source and drain extension implantation step and a halo implantation step may be performed to define source and drain extension regions 253 and to adjust the threshold voltage of the N-channel transistor to be formed in and above the active region 212. The source and drain extension regions 253 define the channel region 215 of the N-channel transistor to be formed. The implantation sequence 205 may further include a pre-amorphization implantation step to reduce the channeling effect during the source and drain extension implantation and the halo implantation.

FIG. 2d schematically illustrates the device 200 in a further advanced process stage in which the gate electrode structure 260 include a further spacer structure 267 that defines a distance from the channel region that is appropriate for forming source and drain cavities and deep source and drain regions of the N-channel transistor to be formed in and above the active region 212. The spacer structure 267 may be formed on the sidewall spacer structure 265 by depositing one or more material layers, such as a silicon nitride layer and/or a silicon dioxide layer, and patterning the same in an anisotropic etch process by well-established manufacturing processes.

FIG. 2e schematically illustrates the device 200 in a further advanced process stage in which a plasma-assisted etch atmosphere is established for etching a cavity 204, which may be accomplished on the basis of well-established process recipes, for instance in the presence of a mask (not shown) covering device regions comprising transistors that are not intended to receive a cavity etch or are intended to receive a separate cavity etch, such as, for example, P-channel transistors. An anisotropic etch process 209 is performed so that the cavity 204 extends through the silicon sub-layer 202A so that the silicon/germanium sub-layer 202B is exposed. The etch process 209 is performed until the cavity 204 extends into the silicon/germanium sub-layer 202B as indicated by reference number 255 so as to reliably expose the silicon/germanium sub-layer 202B. In one embodiment, the cavity 204 extends approximately 1 nm and more into the silicon/germanium sub-layer 202B. In an even more preferred embodiment, the cavity 204 extends approximately 2 nm and more into the silicon/germanium sub-layer 202B.

FIG. 2f schematically illustrates the device 200 in a further advanced process stage during a selective epitaxial growth process 210 in which process parameters are adjusted such that silicon deposition is restricted to crystalline surface areas, while a deposition of silicon on dielectric surface areas is substantially suppressed to selectively form embedded pure silicon regions 250 forming in combination with source and drain extension regions 253 and source and drain regions 254 that extend into the silicon/germanium sub-layer 202B, wherein an interface between the selectively grown embedded silicon drain and source region 250 and the silicon/germanium layer 202B is arranged at a first height level and an interface between the silicon layer 202A and the silicon/germanium layer 202B is arranged at a second height level, wherein the first height level and the second height level are different as indicated by reference number 255, due to the overetching set forth with regard to FIG. 2e.

The term “pure silicon” is used herein to indicate that the content of silicon atoms in the region 250 is 98 percent and more. More preferred the content of silicon atoms in the region 250 is 99 percent and more. The “pure silicon” may, however, include impurities such as, for example, phosphorus or arsenic to improve the conductivity of the silicon material to form appropriate source and drain regions 254. In one embodiment, the cavity 204 (FIG. 2e) may be over-filled to provide raised source and drain regions 254, if appropriate for forming improved source and drain contacts and improving conductivity of the N-channel transistor. Device regions having P-channel transistors may be masked in this process step to avoid deposition of silicon on exposed semiconductor regions. Since the exposed silicon/germanium sub-layer 202B serves as a template layer during the selective growth of the embedded drain and source material, the pure silicon material is grown under tensile strain due to the larger lattice constant of the silicon/germanium alloy. Consequently, the embedded silicon source and drain regions induce a tensile strain into surrounding areas including the channel region of the N-channel transistor to be formed, which enhances, in combination with the corresponding component of the biaxial strain provided in the silicon sub-layer 202A (FIG. 2b), electron mobility in the channel. The resulting strain in the channel length direction is indicated by arrows 252. Source/drain regions of N-channel transistors are typically doped by phosphorous or arsenic with an appropriate concentration. In one embodiment, the embedded source and drain regions 250 are in situ doped so that a corresponding subsequent implant step for forming deep source and drain regions may be omitted. Thus, lattice damage and consequently stress relaxation may be reduced. Subsequently, an annealing step may be performed to activate the incorporated dopant species.

FIG. 2g schematically illustrates the device 200 according to a further advanced manufacturing stage in which silicide regions 256 and 266 may be formed on the embedded source and drain silicon material 250 and on the gate electrode 260, respectively. Prior to forming the silicide, the device 200 is subjected to cleaning processes to prepare the device for silicide formation. In this step, also cap layers, if provided on the gate electrode structure 260, may be removed. Due to the high etch resistivity of pure silicon, the material loss in this manufacturing step may be reduced compared to conventional manufacturing techniques using silicon/carbon as an embedded strain-inducing source/drain material in N-channel transistors. The silicide may be formed by well-established manufacturing processes, for instance on the basis of nickel by blanket depositing a nickel layer and annealing the device to form the nickel silicide. Due to the formation of the silicide on pure silicon, the uniformity of the obtained silicide may be significantly improved compared to conventional strategies, thereby reducing the probability of etching through the metal silicide 256 so that respective device failures may be reduced and thus overall production yield may be increased. Subsequently, contacts (not shown) extending to the silicide regions 256, 266 may be formed to electrically connect the transistor as is, for instance, described above with reference to the device 100.

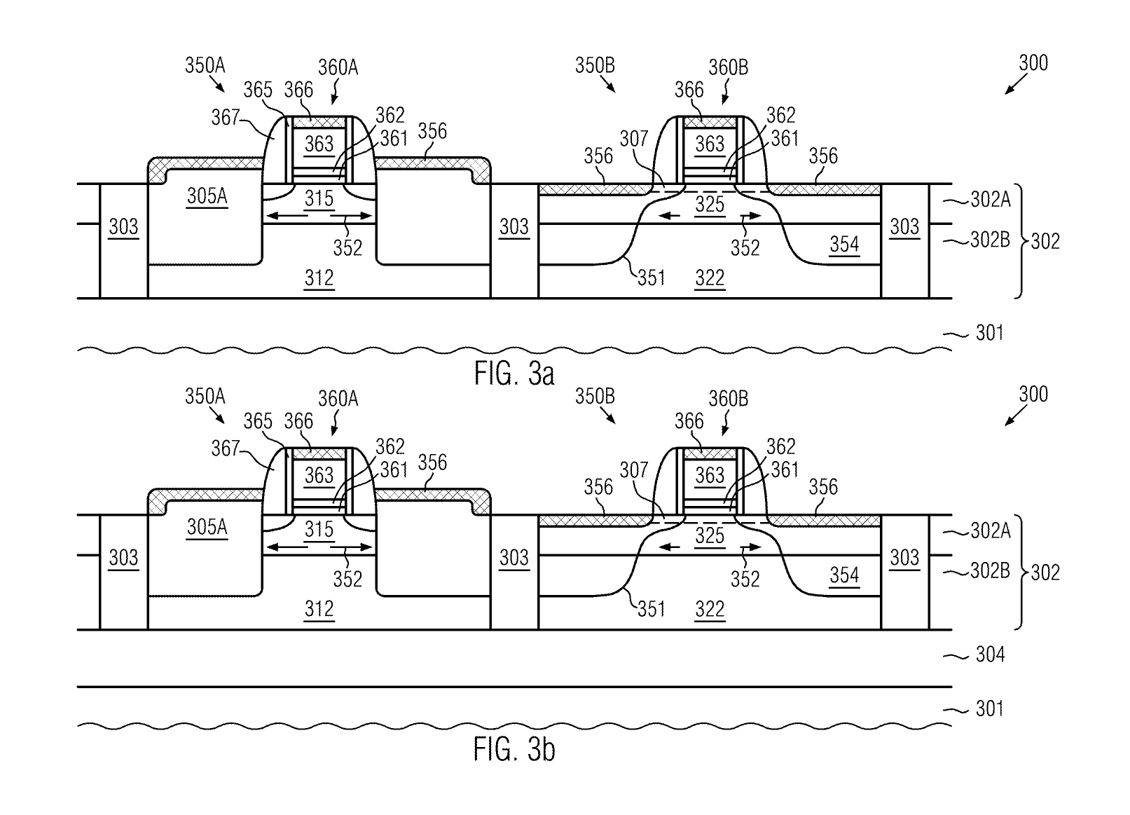

With reference to FIGS. 3a-3b, further illustrative embodiments of the present invention will now be described in more detail in which a CMOS device including an NMOS transistor with embedded strain-inducing source/drain regions is provided.

FIG. 3a schematically illustrates a cross-sectional view of a semiconductor device 300 including a silicon substrate layer 301 having formed thereon a device layer represented by a semiconductor layer 302. The semiconductor layer 302 includes a silicon sub-layer 302A and a silicon/germanium sub-layer 302B, as described with reference to semiconductor device 200. The semiconductor layer 302 is divided into first and second active regions 312, 322 by shallow trench isolation (STI) structures 303. The shallow trench isolation structures 303 extend through the silicon sub-layer 302A and through the silicon/germanium sub-layer 302B of the semiconductor layer 302 to the silicon substrate layer 301. The CMOS device 300 may include an N-channel transistor 350A formed in and above the first active region 312, as described above with reference to device 200, wherein analogous reference numbers comprising a leading “3” instead of a leading “2” are employed. The N-channel transistor 350A may include a dielectric material such as silicon dioxide, silicon oxynitride and/or a high-k material, for example, hafnium-oxide and/or hafnium-silicate. In combination with a high-k material, an additional metal layer 362 may be provided in the gate electrode structure 360A. In embodiments comprising silicon dioxide and/or silicon oxynitride, the metal layer 362 may be omitted as described above with reference to device 200. Strain may be induced into the channel 315 of the N-channel transistor 350A due to the bi-axial strain provided by the strained silicon sub-layer 302A and an additional uni-axial tensile strain induced by the embedded tensile strained silicon source and drain region 305A so that the mobility of the electrons in the channel 315 of the N-channel transistor may benefit from both the bi-axial and the uni-axial tensile strain sources.

The CMOS device 300 further includes a P-channel transistor 350B formed in and above the second active region 322. The P-channel transistor 350B may be formed according to conventional manufacturing processes so that the transistor includes source and drain regions 354 and corresponding PN junctions 351, silicide regions 356 formed in the silicon sub-layer 302A and a silicide region 366 formed on top of the gate electrode structure 360B. The gate dielectric material may be silicon-dioxide, silicon-oxynitride and/or a high-k material, for example, hafnium oxide. In combination with the high-k material, a metal layer 362 may be provided in the gate electrode structure 360B. The metal layer 362 may provide an appropriate work function to adjust the threshold voltage of the transistor 350B in a desired range. In embodiments comprising silicon dioxide and/or silicon oxynitride, the metal layer 362 may be omitted and the threshold voltage may be adjusted by implantation processes. The P-channel transistor 350B may further include an additional channel silicon/germanium layer 307 to further adjust the threshold voltage of the transistor, in particular when the transistor is formed in a so-called gate-first technique according to which a high-k gate dielectric material is provided in an early manufacturing stage of the P-channel transistor 350B. The silicon/germanium layer 307 content may be approximately 20-35 atomic percent germanium. More typically, the germanium content is about 25-30 atomic percent. The thickness of the silicon/germanium layer 307 is in the range of approximately 5-15 nm. More typically, the thickness of the silicon/germanium layer 307 is in the range of approximately 7-10 nm. The channel region 325 of the P-channel transistor 350B may be formed in the silicon sub-layer 302A so that the channel region 325 of the P-channel transistor is also bi-axially tensile strained. The tensile strain provided in the channel width direction of P-channel transistors may improve the mobility of holes so that the performance of the P-channel transistor may be improved by the provided strain conditions, although a tensile strain exerted in the channel length direction of P-channel transistors may adversely affect the performance of the transistor. This effect, however, may be compensated for or even overcompensated for by the tensile strain exerted in the channel width direction so that the overall performance of the P-channel transistor may be improved or at least not substantially reduced. The resulting strain in the channel length directions in the channels of the N-channel transistor 350A and of the p-channel transistor 350B are indicated by arrows 352.

FIG. 3b schematically illustrates a cross-sectional view of a CMOS device 300 including N-channel and P-channel transistors 350A, 350B as described above with reference to FIG. 3a. The device 300 includes a buried insulation layer 304, such as a silicon dioxide layer. The shallow trench isolation structures 303 extend to the buried insulation layer 304 so that the transistors are electrically isolated from the silicon substrate layer 301 and adjacent transistors. Thus, the embodiment relating to FIG. 3b provides an SOI device that may be used in a fully depleted SOI technology based on strained SOI materials.

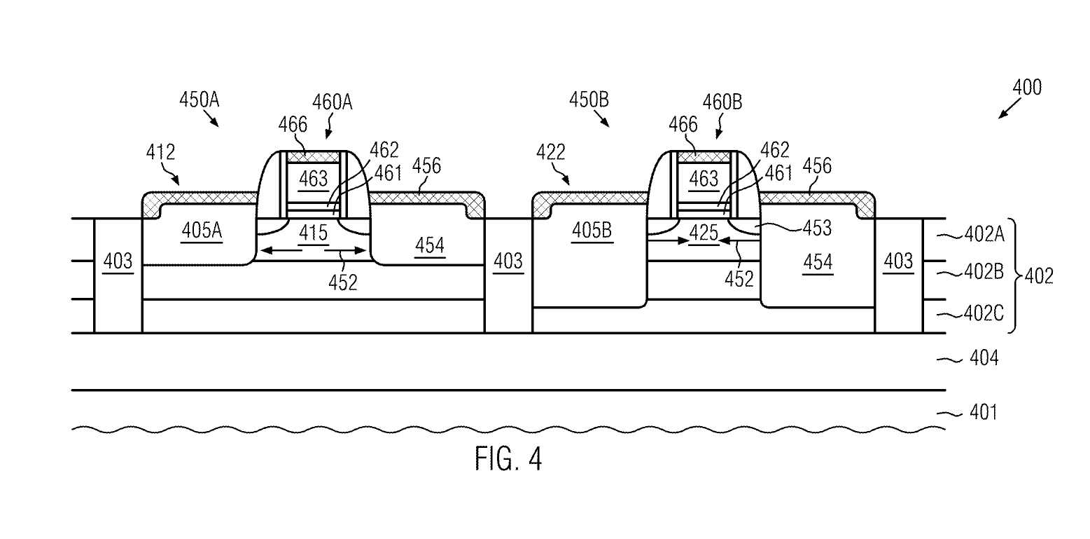

With reference to FIG. 4, a further illustrative embodiment will be described in more detail, wherein reference may also be made to FIGS. 2a-2g and 3a-3b, if appropriate, wherein analogous reference numbers comprising a leading “4” instead of a leading “2” or “3” are employed. FIG. 4 schematically illustrates a cross-sectional view of a CMOS device 400 including a substrate 401, a buried insulation layer 404 and a device layer formed by a semiconductor layer 402. The semiconductor layer 402 includes an upper silicon sub-layer 402A, a silicon/germanium sub-layer 402B and a lower silicon sub-layer 402C. The semiconductor layer 402 may be divided into first and second active regions 412, 422 by shallow trench isolation structures 403 extending through the sub-layers 402A, 402B, 402C of the semiconductor layer 402 to the buried insulation layer 404. An N-channel transistor 450A may be formed in and above the first active region 412, as described above with reference to the devices 200 and 300. The transistor 450A, contrary to the transistor 350A (FIG. 3b), includes a portion of the lower silicon sub-layer 402C. The performance of the N-channel transistor 450A, i.e., the electron mobility in the channel, may benefit from the bi-axial tensile strain provided by the silicon-silicon/germanium sub-layers 402A, 402B and by the embedded uni-axial tensile strain-inducing silicon source/drain material 405A as described with reference to the N-channel transistor 350A.

The P-channel transistor 450B includes an embedded compressive strain-inducing silicon/germanium source and drain material 405B that induces a uni-axial compressive strain in the channel region in the channel length direction that improves the hole mobility in the channel region 425 of the P-channel transistor 450B in addition to the channel width component of the bi-axial tensile strain provided by the strained upper silicon sub-layer 402A. The embedded compressive strain-inducing silicon/germanium source/drain material 405B is selectively grown in cavities extending to the lower silicon sub-layer 402C having a smaller lattice constant than the silicon/germanium material so that the silicon/germanium material is grown with a compressive strain resulting in a uni-axial compressive strain induced in the channel region 425 of the P-channel transistor 450B. The uni-axial compressive strain induced in the channel region 425 in the channel length direction may overcompensate for the corresponding tensile strain component of the bi-axial tensile strain caused by the strained silicon sub-layer 402A. Thus, the N-channel transistor 450A, as well as the P-channel transistor 450B, exhibits optimized strain conditions in the channel regions 415, 425 increasing the mobility of electrons and holes, respectively. The resulting strain in the channel length directions in the channels of the N-channel transistor 450A and of the P-channel transistor 450B are indicated by arrows 452. The embedded compressive strain-inducing silicon/germanium source/drain material 405B content may be approximately 25-35 atomic percent germanium. More typically, the germanium content is about 30 atomic percent. The embedded strain-inducing silicon/germanium material 405B may be in situ doped with boron having an appropriate concentration to form, in combination with source and drain extension regions 453, source and drain regions 454.

As a result, the present disclosure provides manufacturing techniques and semiconductor devices in which an efficient strain-inducing embedded source/drain material is provided, in particular in N-channel transistors, on the basis of an embedded pure silicon material that is grown on a silicon/germanium template layer. The silicon source/drain material may further improve the N-channel transistor with regard to material loss due to the superior etch resistivity of pure silicon and with regard to contact aspects, due to the superior uniformity of the silicide due to improved conditions for silicide formation compared to conventional manufacturing techniques having embedded silicon/carbon materials.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention.

Accordingly, the protection sought herein is as set forth in the claims below.

What is claimed:

1. A method, comprising:
providing a substrate comprising a silicon layer formed on a silicon/germanium layer;
forming an isolation structure extending through said silicon layer and through said silicon/germanium layer to define an active region;
forming a gate electrode structure comprising a spacer structure on said silicon layer;
forming cavities in said active region adjacent to said gate electrode structure, said cavities extending through said silicon layer to expose said silicon/germanium layer; and
selectively growing silicon in said cavities using said exposed silicon/germanium layer as a template layer.

2. The method of claim 1, wherein said silicon/germanium layer is formed on a silicon substrate layer.

3. The method of claim 1, wherein said silicon/germanium layer is formed on a buried insulation layer.

4. The method of claim 1, wherein a concentration of silicon of said selectively grown silicon comprises approximately 99 percent and more.

5. The method of claim 1, wherein an interface between said selectively grown silicon and said silicon/germanium layer is arranged at a first height level and an interface between said silicon layer and said silicon/germanium layer is arranged at a second height level, wherein said first height level and said second height level are different.

6. The method of claim 5, wherein a difference between said first height level and said second height level is approximately 1 nm and more.

7. The method of claim 1, further comprising forming strained source and drain regions of an N-channel transistor in said selectively grown silicon.

8. The method of claim 7, wherein said strained source and drain regions of said N-channel transistor are in situ doped during said selective silicon growth process.

9. The method of claim 1, further comprising forming a silicide on said selectively grown silicon.

10. A semiconductor device, comprising:
a substrate comprising a silicon/germanium layer and a silicon layer formed on said silicon/germanium layer;
an active region defined by an isolation structure extending through said silicon layer and through said silicon/germanium layer;
a gate electrode structure comprising a spacer structure and being formed on said silicon layer; and
an embedded strained silicon region formed on said silicon/germanium layer in source and drain regions of an N-channel transistor.

11. The semiconductor device of claim 10, wherein said silicon/germanium layer is formed on a silicon substrate layer.

12. The semiconductor device of claim 10, wherein a concentration of silicon in said embedded strained silicon region comprises approximately 99 percent and more.

13. The semiconductor device of claim 10, wherein an interface between said embedded strained silicon region and said silicon/germanium layer is arranged at a first height level and an interface between said silicon layer and said silicon/germanium layer is arranged at a second height level, wherein said first height level and said second height level are different.

14. The semiconductor device of claim 13, wherein a difference between said first height level and said second height level is approximately 1 nm and more.

15. A semiconductor device, comprising:
a substrate comprising a silicon-silicon/germanium-silicon layer stack defining an upper silicon layer and a lower silicon layer;
a first and a second active region defined by isolation structures extending through said silicon-silicon/germanium-silicon layer stack;
a first and a second gate electrode structure comprising a spacer structure, said first and said second gate electrode structures being formed on the upper silicon layer of said silicon-silicon/germanium-silicon layer stack;
embedded strained silicon regions formed on said silicon/germanium layer in source and drain regions of a transistor formed in said first active region; and
embedded strained silicon/germanium regions formed on said lower silicon layer in source and drain regions of a transistor formed in said second active region.

16. The semiconductor device of claim 15, wherein a concentration of silicon in said embedded strained silicon region comprises approximately 99 percent and more.

17. The semiconductor device of claim 15, wherein said silicon-silicon/germanium-silicon layer stack is arranged on an insulation layer and said isolation structures extend to said insulation layer.

18. The semiconductor device of claim 15, wherein said transistor formed in said first active region is an N-channel transistor and said transistor formed in said second active region is a P-channel transistor.

19. The semiconductor device of claim 18, wherein, in said N-channel transistor, an interface between said embedded strained silicon region and said silicon/germanium layer is arranged at a first height level and an interface between said silicon layer and said silicon/germanium layer is arranged at a second height level, wherein said first height level and said second height level are different.

20. The semiconductor device of claim 19, wherein a difference between said first height level and said second height level is approximately 1 nm and more.
